(19) United States
(12) Patent Application Publication
(10) Pub. No.: US 2004/0131127 A1
(43) Pub. Date: Jul. 8, 2004

(54) Rfic transceiver architecture and method for its use

(76) Inventors: Zivi Nadiri, Mazkeret Batya (IL); Raviv Melamed, Nes Ziona (IL)

Correspondence Address: Mark Friedman, Bill Polkinghorn, Discovery Dispatch, 9003 Florin Way, Upper Marlboro, MD, 20772, US

(21) Appl. No.: 10/479,055

(22) PCT Filed: Aug. 27, 2002
(86) PCT No.: PCT/US02/27191

(51) Int. Cl. H03K 7/06; H03K 9/06

(52) U.S. Cl. 375/271

(57) ABSTRACT

A method of converting RF to base-band signals, or base-band to RF signals, using a novel receiver and transmitter architecture, implementable on a RFIC. The method uses a two-stage conversion sequence: RF to base-band followed by base-band to intermediate frequency in the receiver, and an opposite sequence in the transmitter. A preferred embodiment of the architecture uses a double balance quadrature demodulator (208) for the RF to base-band down-conversion, and an image reflect quadrature modulator (230) for the base-band to intermediate frequency conversion. The architecture is further enhanced to perform power saving and dual-band reception and transmission.

### FIELD AND BACKGROUND OF THE INVENTION

The present invention relates to radio frequency (RF) chips, also known as RF integrated circuits (RFIC), specifically to architectures that result in RFICs with high performance/cost ratios. More specifically, the present invention relates to methods of converting RF to base-band signals or base-band to RF signals using a novel receiver and transmitter architecture on a RFIC.

RFICs are known in the art, and find widespread use in wireless telecommunication. There are various methods for conversion of RF to base-band and base-band to RF signals that can be implemented using RFICs. Two of the most widely used methods are Double Conversion and Direct (or Zero IF) Conversion. For a typical double conversion, FIG. 1 shows a RF receiver 10 that has an input RF signal 20 amplified and filtered by a wide band filter (not shown) and then down-converted to an intermediate frequency (IF) signal 22 in a first RF-to-IF conversion stage 24. IF signal 22 undergoes further amplification and narrow band filtering and is then further down-converted to a base-band (BB) signal 26 in a second, down-converter IF-to-BB quadrature (IQ) conversion stage 28, after which the analog signal is digitized in a dual A/D converter 30. The IF frequency value and the filters along the conversion stages are designed such as to provide rejection of out-of-band signals, and in particular rejection at the image frequency band. A double conversion transmitter operates essentially in a reverse manner, that is first a digital signal is transferred to analog in a dual D/A converter operating at the base-band, then the signal is quadrature up-converted to IF and then, in a second conversion stage, further up-converted to RF. While double conversion provides a very high performance receiver, it requires expensive components external to the RFIC (especially the IF narrow band filters) and as such results in an expensive and complicated overall solution.

In Direct (Zero IF) Conversion, FIG. 2, there is no intermediate frequency band use. Instead, a RF receiver 40 receives a RF signal 42 and down-converts it directly to a base-band signal 46 in a RF-to-BB quadrature conversion stage 44, after which the analog signal is digitized in a dual A/D converter 48. Amplification and wideband filtration (not shown) is performed on RF signal 42 prior to down-conversion, while further dual amplification and narrowband filtering is performed (not shown) following down conversion to base-band and prior to digitization. A direct conversion transmitter operates essentially in a reverse manner, that is first a digital quadrature signal is transferred to analog in a dual D/A converter, then the signal is directly quadrature up-converted to RF. The big advantage of the direct conversion lies in the fact that with no IF frequency, the receiver does not have to consider rejection of signals at the insane frequency band. This may simplify the receiver by having less external parts, etc. However, its implementation in a RFIC architecture is problematic. In a direct conversion receiver, the amplification and rejection of unwanted signals are performed on the input signals following the conversion to base-band. There is an inherent difficulty in designing high performance amplification and rejection within a typical low cost RFIC technology, i.e. design to handle internally generated noise, unwanted DC signals, amplitude and phase matching between the dual base-band paths, etc.

There is thus a widely recognized need for, and it would be highly advantageous to have, a RFIC with good performance at a reasonable cost, i.e. a high performance and cost effective RFIC.

### SUMMARY OF THE INVENTION

The present invention discloses a method of converting RF to base-band signals, or base-band to RF signals, using a novel receiver and transmitter architecture, implementable on a RFIC. The method uses a two-stage conversion sequence: RF to base-band followed by base-band to intermediate frequency in the receiver, and an opposite sequence in the transmitter.

According to the present invention, there is provided in a first embodiment a method for efficiently converting a RF signal into a digital signal, comprising: receiving the RF signal, down-converting the received RF signal to a base-band frequency range to obtain a base-band signal, up-converting the base-band signal to a low intermediate frequency range to obtain a low IF signal, and converting the low IF signal into a digital signal.

According to one feature in the first embodiment of the method of the present invention, the down-converting of the received RF signal to a base-band frequency range includes demodulating the RF signal with a quadrature demodulator, and the up-converting of the base-band signal to a low intermediate frequency range includes modulating the RF signal with a quadrature modulator.

According to another feature in the first embodiment of the method of the present invention, the demodulating of the RF signal with a quadrature demodulator includes demodulating the RF signal with a double-balanced quadrature demodulator.

According to yet another feature in the first embodiment of the method of the present invention, the quadrature demodulator is a sub-harmonic quadrature demodulator.

According to yet another feature in the first embodiment of the method of the present invention, the modulating of the base-band signal is done with an image-reject quadrature modulator.

According to yet another feature in the first embodiment of the method of the present invention, the modulating of the base-band signal with a quadrature modulator includes modulating the base-band signal with an image-reject quadrature modulator.

According to yet another feature in the first embodiment of the method of the present invention, the modulating of the base-band signal With a quadrature modulator includes modulating the base-band signal with an image-reject quadrature modulator.

According to the present invention, there is a method for efficiently converting a digital signal into a RF signal for RF transmission, comprising: generating a digital signal in a low intermediate frequency range, converting the digital signal into an analog signal to obtain a low IF signal, down-converting the low IF signal to a base-band frequency range to obtain a base-band signal, and converting the base-band signal to a RF signal used for RF transmission.

According to one feature in the method of the present invention for efficiently converting a digital signal into a RF signal for RF transmission, the down-converting of the low IF signal to a base-band frequency range includes using a quadrature demodulator, and the up-converting of the base-band signal to a RF signal includes using a quadrature modulator.

According to another feature in the method of the present invention for efficiently converting a digital signal into a RF signal for RF transmission, the quadrature modulator is a double-balanced quadrature modulator.

According to yet another feature in the method of the present invention for efficiently converting a digital signal into a RF signal for RF transmission, the quadrature modulator is a sub-harmonic quadrature modulator.

According to the present invention, there is provided a system for converting RF signals into digital signals, comprising: a down-converter used to convert an analog RF signal into a base-band signal, and an up-converter connected to the down-converter and used to convert the base-band signal into a low intermediate frequency signal which is further processed into a digital signal.

According to one feature in the system for converting RF signals into digital signals of the present invention, the down-converter and the up converter include respectively a down-converter quadrature demodulator and for up-converter quadrature modulator.

According to another feature in the system for converting RF signals into digital signals of the present invention, the system is implemented on a RFIC.

According to yet another feature in the system for converting RF signals into digital signals of the present invention, the RFIC is manufactured using a technology selected from the group consisting of SiGe and RF CMOS technologies

According to yet another feature in the system for converting RF signals into digital signals of the present invention, the down-converter quadrature demodulator includes a double balanced quadrature demodulator.

According to yet another feature in the system for converting RF signals into digital signals of the present invention, the quadrature demodulator is a sub-harmonic quadrature demodulator

According to yet another feature in the system for converting RF signals into digital signals of the present invention, the up-converter quadrature modulator includes an image-reject quadrature modulator.

According to the present invention, there is provided a system for converting a digital signal into a RF signal comprising: a down-converter used to convert a low intermediate frequency analog signal obtained from the digital signal into a base-band signal, and an up-converter connected to the down-converter and used to convert the low intermediate frequency signal into a RF signal.

According to one feature in the system for converting digital signals into RF signals of the present invention, the down-converter and up-converter include, respectively, a down-converter quadrature demodulator and an up-converter quadrature modulator.

According to another feature in the system for converting digital signals into RF signals of the present invention, the system is implemented on a RFIC.

According to yet another feature in the system for converting digital signals into RF signals of the present invention, the RFIC is manufactured using a technology selected from the group consisting of SiGe and RF CMOS technologies.

According to the present invention there is provided an efficient, power saving receiver system for converting an input analog RF signal into a digital signal, comprising: a RF plus IF section that generates a low intermediate frequency signal that is further processed into the digital signal, a digital section connected to the RF plus IF section to process the digital signal, and detector means coupled to sample the low intermediate frequency signal between the RF plus IF section and the digitail section, whereby the detector means enable stand-by (power-save) mode operation by turning on and off the digital part of the system.

According to one feature in the efficient, power saving receiver system for converting an input analog RF signal into a digital signal, the RF plus IF section includes a down-converter used to convert the analog RF signal into a base-band signal, and an up-converter connected lo the down-converter and used to convert the base-band signal into the low intermediate frequency signal.

According to the present invention there is provided a system for reception and transmission of RF signals belonging to either a RF low frequency band or a RF high frequency band, comprising: a receiver for converting either the low frequency band or the high frequency band RF signals to base-band or intermediate frequency, wherein the conversion of the high band RF signals is obtained by standard down-conversion, and wherein the conversion of the low band RF signals is obtained by first up-converting them into outcome high band RF signals, and then down-converting the outcome high band RF signals, and a transmitter for converting base-band or intermediate frequency signals into either low band or high band RF signals for RF transmission, wherein the conversion to the high band RF signals is performed by standard up-conversion, and wherein the conversion to the low band RF signals is obtained by first up-converting the base-band or intermediate frequency signals to obtain outcome high band RF signals, and then down-converting the high band outcome RF signals.

According to one feature in the system for reception and transmission of RF signals belonging to either a RF low frequency band or a RF high frequency band, the conversion of the low band signals obtained by first lip-converting them into high band reception signals is performed in a block up-converter, and the conversion to low band transmission signals is per formed in a block down-converter.

According to another feature in the system for reception and transmission of RF signals belonging to either a RF low frequency band or a RF high frequency band, the high band signals and the low band signals are respectively 5 GHz and 2.4 GHz signals according to the IEEE 802.11a, IEEE802.11b and IEEE802.11g standards.

### BRIEF DESCRIPTION OF THE DRAWINGS

The invention is herein described, by way of example only, with reference to the accompanying drawings, wherein:

FIG. 1 shows a schematic block diagram of a RF-to-digital double conversion process;

FIG. 2 shows a schematic block diagram of a RF-to-digital direct (zero IF) conversion process;

FIG. 3 shows a schematic block diagram of a RF-to-digital conversion process according to the present invention;

FIG. 4 shows a preferred embodiment of a transmit and receive block diagram according to the present invention,

FIG. 5 shows schematically an image-reject quadrature modulator;

FIG. 6 shows an enhancement, which enables stand-by operation;

FIG. 7 shows a schematic block diagram of a transmit and receive system that supports dual band operation;

FIG. 8 shows a schematic block diagram of a modified transmit and receive system that supports dual band operation;

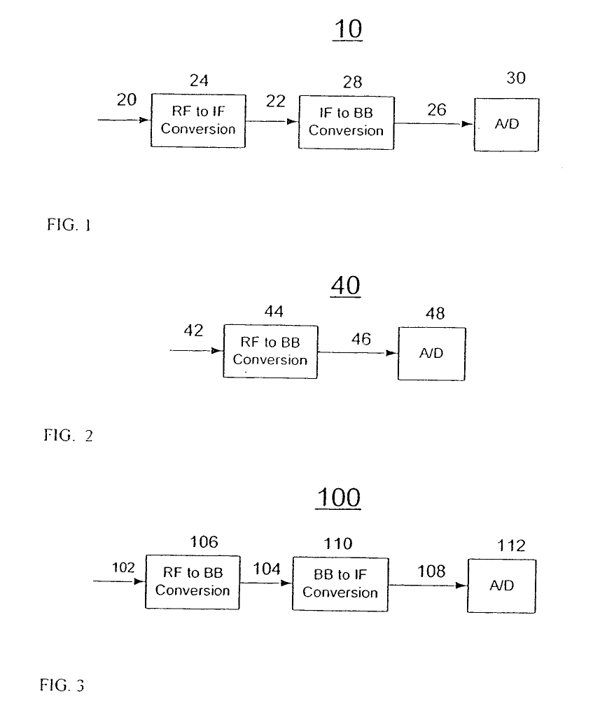

### DESCRIPTION OF THE PREFERRED EMBODIMENTS

The present invention relates to RFICs, specifically to architectures or topologies that result in RFIC with high performance/cost ratios. More specifically, the present invention relates to methods of converting RF to base-band signals or base-band to RF signals using a novel receiver and transmitter architecture on a RFIC. The topology presented herein combines the main advantages of the direct (zero IF) and the low IF (near Zero) conversion approaches. The basic idea is to first down-convert the received signal to base-band, and then up-convert it to a low IF frequency. This sequence of steps is illustrated in FIG. 3, which shows in a block diagram the main elements of the topology and their use. Thus, in FIG. 3, a receiver 100 receives a RF signal 102 which is then down-converted to a base-band signal 104 in a first RF-to-BB converter stage 106. This first down-conversion is similar to the direct (zero IF) conversion of FIG. 2. However, in a novel step, base-band signal 104 is then up-converted to a low IF signal 108 in a second BB-to-IF conversion stage 110. Signal 108 at low IF frequency is then converted to a digital signal in an A/D converter 112. Further processing, including down-conversion from low IF to base-band, is performed on the signal by a digital signal processor, Which is typically not part of the RFIC. The two stage, RF-to-BB followed by BB-to-IF conversion is unlike any conversion sequence in any prior art receiver.

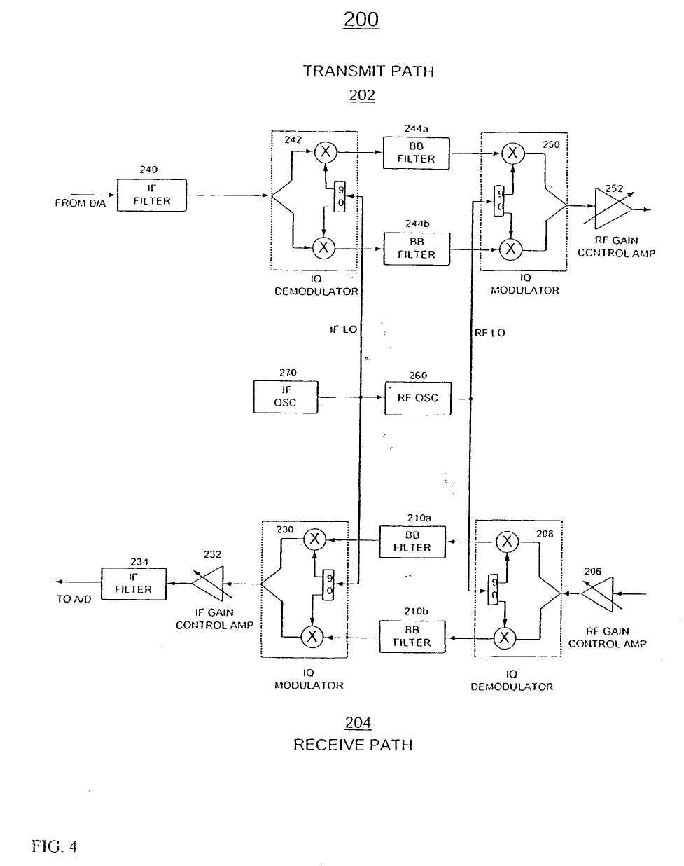

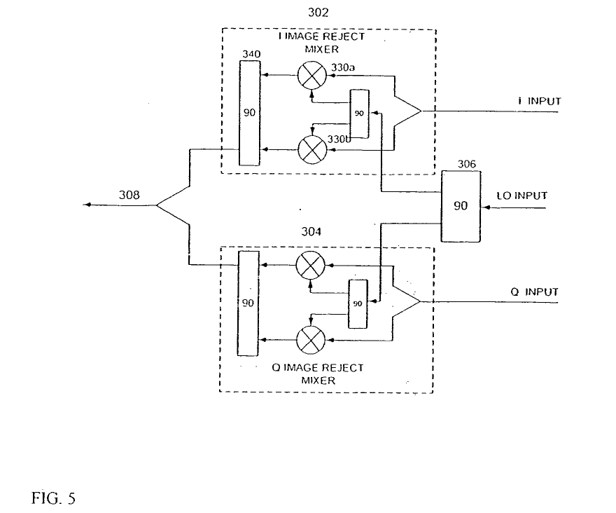

FIG. 4 shows, in more detail, the topololy of a preferred embodiment transceiver system that can be implemented in a RFIC according to the present invention. A transceiver system 200 includes a transmit (up-conversion) chain or path 202 (hereafter “transmitter 202”) and a receive (down-conversion) chain or path 204, (hereafter “receiver 204”), both of which include the same sequence of two RF-to-BB and BB-to-IF conversion stages. Since the transmitter elements essentially mirror those of the receiver, we discuss the receiver in detail, with the understanding that this discussion refers to the transmitter too (which however is operated in essential a reverse manner to the receiver). However, the considerations and trade-offs for the up-conversion chain and for the down-conversion chain are different, and they are analyzed separately below.

Receiver 204 includes a RF gain control amplifier 206 connected to a quadrature (IQ) demodulator 208, which is in turn connected to two BB filters 210a and 210b. A RF oscillator, topically a synthesizer 260 provides the required local oscillator (LO) input to demodulator 208. Components 206, 208, 210a, b and 260 perform the direct conversion where the RF signal is amplified and wide-band filtered by RF amplifier 206 and quadrature down-converted by demodulator 208 to base-band. Rejection of close-by signals is provided by the two base-band filters 210a and 210b. Due to the direct conversion method, there are no image frequency issues to be taken into consideration. Filters 210a, b are connected to a quadrature. modulator 230, which is preferably an image-reject quadrature modulator. Modulator 230 is further connected through an IF gain control amplifier 232 to an IF filter 234. A low IF oscillator 270 provides the required LO input to modulator 230. Usually, oscillator 270 is also the input reference frequency source to synthesizer 260. Components 230, 232, 234 and 270 perform an up-conversion of the dual base-band signal to low IF. Modulator 230 up-converts the base-band signal, and for an image-reject modulator it complements the base-band filtering by rejecting residual unwanted signals at 2 times the above low IF frequency (also known as “image” frequency). An amplifier 232 provides signal variable amplification at low IF, replacing the problematic dual base-band amplification (one amplifier for the I path and another for the Q path) present in direct conversion receiver of FIG. 2. Its output is further filtered by narrow-band filter 234.

While any quadrature demodulator can be used in the topology of FIG. 4, in order to maintain low LO and DC leakage, large inter-modulation rejection and a very high IP2 (second-order intercept point) value, a preferred implementation of the receive chain includes a double balanced quadrature demodulator as demodulator 208 In particular, demodulator 208 is preferably a sub-harmonic double balanced quadrature demodulator where the input LO frequency is at half the output RF frequency. A major advantage of using a sub-harmonic demodulator is in providing inherent immunity against pulling of the voltage-controlled oscillator (VCO—not shown), which is an integral part of synthesizer 260. Non-sub-harmonic demodulators, i.e. demodulators with LO frequency equal to RF output frequency can also be used, having the synthesizer operating at half the RF frequency (to prevent pulling) and followed by a frequency doubler.

Image-reject quadrature modulator 230 used in the topology of FIG. 4 has been selected as the most preferred modulator since it provides additional rejection of interfering signals, and as such eliminates the need for high selectivity on base-band filters 210a,b. However, the conversion method described herein can in principle use other modulators, as discussed below, The structure of the image-reject quadrature modulator is based on a conventional quadrature modulator, however instead of standard mixers we use image-reject mixers. A more detailed view of an image-reject quadrature modulator is shown in FIG. 5.

In FIG. 5, an image-reject quadrature modulator 300 includes an I image reject mixer 302 receiving an I input, and a Q image reject mixer 304 receiving a Q input, the two reject mixers connected to each other and to a LO input through a 90° shifter 306. The outputs of the two image reject mixers are added to generate a combined output 308. Image reject mixer 302 has a construction where the I input signal is up-converted by two identical mixers 330a, b, driven by two LO signals that are in quadrature (90° phase) one with respect to the other. The outputs of these mixers are combined in quadrature through a 90° phase shifter 340. Q image reject mixer 304 has an identical construction. Image reject mixers are well known in the art (see e.g. B. Razavi, “RF Microelectronics”, Prentice Hall, 1998). A important and advantageous property of the image-reject quadrature modulator of FIG. 5 is that, as it up-converts the I and Q signals to an IF frequency, it rejects all signals which are about 2 times IF frequency apart from the wanted signal Thus, it provides a means to reject unwanted signals that are near the wanted signal, and eases selectivity requirements of the base-band filters.

Regarding implementation of the down-conversion chain in a RFIC, the advantages of the proposed topology include:

1. There is no image at the RF band, as the down-conversion is basically of the direct conversion type. As such there is no need for an image reject filter as part of the down-conversion process.

2. The l/Q (gain/phase) balance requirement as induced by quadrature demodulator 208 and base-band filters 210a, b (FIG. 4) is similar to the one required when using conventional direct conversion topology, typically 35 dB in a sideband rejection test.

3. Use of an image-reject quadrature modulator as up-converter eases the selectivity requirements on base-band filters 210a, b, and as such simplifies the design.

4. To compensate the dynamic range of the input signal, variable amplification is provided at the IF stage by IF gain control amplifier 232. A single amplifier (compared to the two required in a full direct conversion topology) has no implication on the matching and tracking between the I and Q paths.

5. High gain amplification at IF gain control amplifier 232, is typically implemented by a cascade of low gain amplifiers, AC-coupled so they can be separately biased, and as such achieve higher dynamic range. In addition, AC-coupled amplifiers are free of DC offset problems (a crucial problem for amplifiers in the I and Q base-band path of the direct conversion topology.

6. A typical value for low IF is 10 to 40 MHz. This value should be larger than the signal bandwidth, but sufficiently low to enable sampling by an A/D converter. Nevertheless, this frequency is sufficiently high so that the l/frequency dependent noise, generated by the internal components of the RFIC, is negligible.

7. The low IF signal is converted into a digital format by a single A/D, while direct conversion topology requires two A/Ds, with carefully matched parameters.

Finally, with the present topology, axle need a single, common LO source for receive down-converting (from RF to base-band) and for transmit up-converting (from base-band to RF). The same applies for the LO that converts the base-band to low IF and vice versa. Typically, the LO source for the low IF conversion is also the reference frequency source of the RF oscillator (synthesizer) for the RF conversion. A side benefit of this scheme is that all frequency sources are phase locked to a common reference.

FIG 4 shows the details of the transmitter (up-conversion chain). In the transmitter, low IF signals in digital representation are converted to analog form using D/A converters. An advantage of the transmitter topology disclosed herein is the fact that it uses a single D/A converter instead of a dual D/A converter needed when the input is a dual (I and Q) base-band signal and the topology is standard direct conversion. Conversion of the low IF input signal to high RF frequency by using a single stage up-conversion generates an unwanted component (off in frequency from the wanted component by 2 times IF), which should be appropriately filtered. This is typically impractical (due to the low value of the IF) so another approach is required. In the transmitter topology disclosed herein, the above problem is avoided because the IF signal is down-converted to quadrature base-band, and filtered to remove unwanted components at the sampling frequency and its harmonics The down-conversion is performed by a quadrature demodulator. Following filtering, the base-band signal is up-converted by a quadrature modulator. In particular, this can be a double balanced quadrature modulator, which minimizes LO leakage. Similar to the receiver, the upconverting quadrature modulator can be of a sub-harmonic type, i.e. the local oscillator input signal frequency is half of the output RF frequency.

To summarize, in general, the scope of present invention includes the use of any combination of double-balanced quadrature demodulators, image-reject quadrature modulators, and standard quadrature modulators and quadrature demodulators for the transmit and receive chains. While the preferred embodiments of both transmitter and receiver elements have been described above, in general the transmit chain may use double-balanced quadrature demodulators, while the receive chain may use standard quadrature demodulators or quadrature modulators.

We note that the transmitter, receiver, and the combined transmitter/receiver topologies described herein can be implemented with discrete components, in addition to their preferred implementation in a RFIC. Alternatively, and within the scope of this invention, there may be a combined use of RFIC and discrete elements. For example, sections of the receive and transmit chains may be implemented on a RFIC using SiGe or RF CMOS technology and connected to other, discrete elements. When implemented in an RFIC, the transmitter, receiver, and the combined transmitter/receiver topologies described herein are particularly useful in RFICs designed for use in a wireless local area network (WLAN) system. More particularly, RFICs using the proposed topologies can be incorporated in WLAN systems based on IEEE standards IEEE802.11a (5-6 GHz) or IEEE802.11b (2.4-2.5 GHz) or IEEE802.11g (2.4-2.5 GHz).

Power Saving Mode Solution

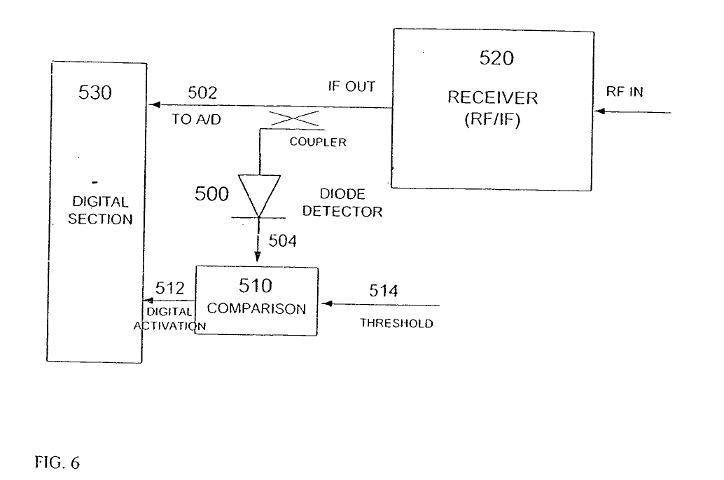

One of the most critical issues of any receiver design is the power consumption. In general, a receiver topology can be divided into two sections: a digital and processing section, and a “RF+IF” section. In most scenarios, a lot of DC power is dissipated even when no signal is received, as the digital and processing section of the receiver (which typically is a large power consumer) is turned on at all times, “waiting” for an incoming signal. The operation of any receiver having the two sections above, and, in particular, the operation of the receiver of the present invention as embodied in the various preferred embodiments of FIGS. 4, 7 and 8 and their description, can be advantageously enhanced to improve power consumption by adding a simple “signal presence” detection circuit. This is shown in FIG. 6, where the input of a detector means 500 that includes for example a diode based detector, is coupled to the IF signal 502 exiting a RF+IF section 520, generating an output 504 proportional to the strength of the received signal. This output is connected to a comparison circuit 510 that provides a signal 512 used to activate a digital and processing section 530 In contrast with the situation in prior art, where the digital and processing section of a receiver is always “on”, this circuit enables a system, and in particular the systems described herein to operate in a stand-by (power save) mode, where during this stand-by mode only the RF+IF section of the receiver is activated, while the digital and processing section is turned off. The comparison circuit senses the level of the input signal and activates the digital section only when the input signal is above a threshold level 514. By changing the threshold level, it is possible to control the received signal strength that activates the digital processing section.

Dual Band Architecture

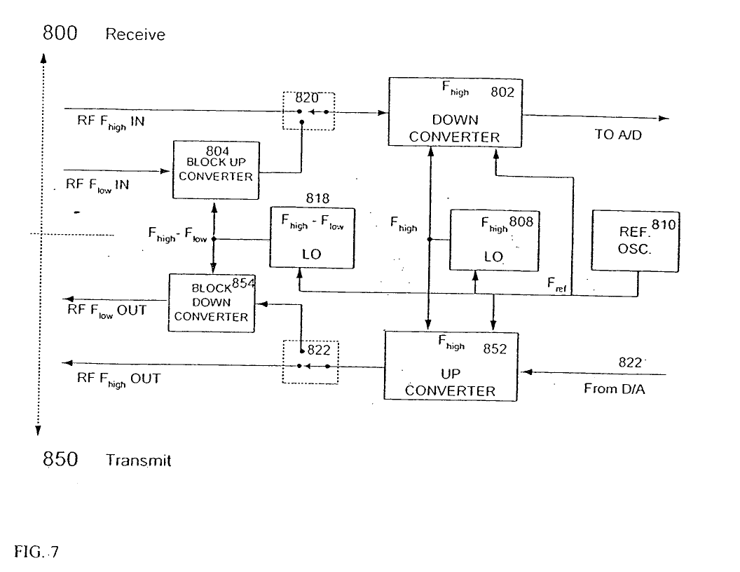

Many standard dual-band radio transceivers operate in two disjoint frequency bands and are implemented by doubling the complete receive and transmit path, so that each band is handled separately. This is done regardless of the transceiver topology, e.g. regardless whether it is double-conversion or direct conversion. An example is a multi-mode wireless LAN with one band around 5 GHz (“F_{high}”) supporting IEEE802.11a and other around 2.4 GHz (“F_{low}”) supporting IEEE802.11b or IEEE802.11g. The aim is to support both bands with as much commonality as possible, from the implementation point of view. The architecture and topology disclosed herein can be advantageously used for dual-band purposes, as explained using FIG. 7. FIG. 7 shows a schematic block diagram of a transmit and receive system that supports dual band operation. The figure shows a receive path (receiver) 800 that includes a down-converter 802 connected to a block up-converter 804, and a transmit path (transmitter) 850 that includes an up-converter 852 connected to a block down-converter 854. When receiver 800 receives a high band signal F_{high}IN, the receiver uses down-conversion from RF (high band) to base-band, performed in down-converter 802 preferably by the method described above, or optionally any other known method. When receiver 800 receives a low band signal F_{low}IN the signal is first up-converted from the low band to the high band using block up-converter 804 which up-converts the whole low band to the high band). The up-converted signal is routed through a selector/switch 820 to down-converter 802, from there following the path of the high band signal.

In the transmit path, the procedure is similar: transmitter 850 up-converts an input signal 822 received from an A/D converted (not shown) to a high band output signal RF F_{high}OUT, using up-converter 852. This up-conversion can be done using any known standard technique. To obtain a low hand output RF signal F_{low}OUT, input signal 822 is first up-converted to the high band using up-converter 852, then routed through selector/switch 822 and down-converted to the low-band using block down converter 854.

In FIG. 7, the high band receive down-converter and transmit up-converter use as LO a RF oscillator 803 and optionally an additional oscillator 810 as an IF LO. Typically the IF oscillator is also a frequency reference for the RF oscillator. Block up-converter 804 (for the receive low band) and block down-converter 854 (for the transmit low band) use as LO a source 818 at frequency F_{high}-F_{low}, typically locked to the same frequency reference 810.

The dual band architecture of FIG. 7 adds two block converters (804 and 854) and an additional oscillator source 818 with respect to a standard transceiver operating in one band. The major innovative aspect lies in the specific architecture (block converting) while maintaining a high degree of commonality with a single band transceiver. This in contrast with other prior art methods that use separate dedicated converters for each band.

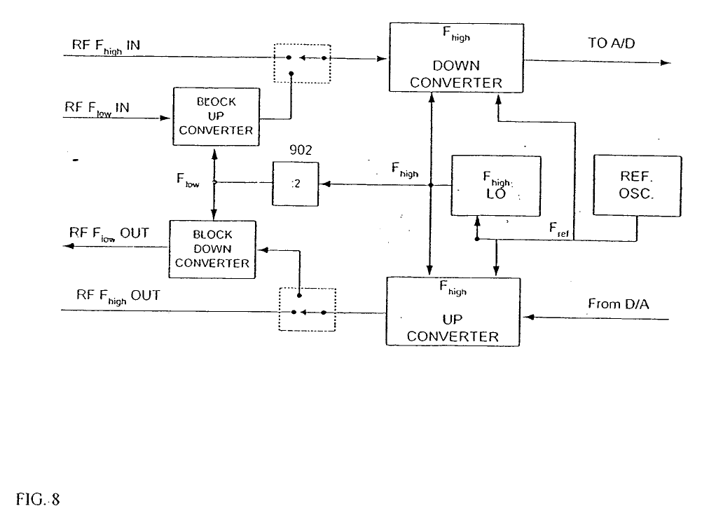

FIG. 8 Shows a schematic block diagram of a modified transmit and receive system that supports dual band operation. This system is a variation on the above, and is applicable when the frequency of the low band is approximately half of that of the high band (i.e. F_{low}is about half of F_{high}, e.g. 2.4 GHz and 5 GHz respectively). In this case, the oscillator (818 in FIG. 7) for the block converters is not needed and can be removed, while the LO frequency required by the block converters is generated by feeding the F_{high} synthesizer (803 in FIG. 7) output to a “divide by 2” circuit 902.

All publications mentioned in this specification are herein incorporated in their entirety by reference into the specification, to the same extent as if each individual publication was specifically and individually indicated to be incorporated herein by reference. In addition, citation or identification of any reference in this application shall not be construed as an admission that such reference is available as prior art to the present invention.

While the invention has been described with respect to a limited number of embodiments, it will be appreciated that many variations, modifications and other applications of the invention may be made.

What is claimed is

1. A method for efficiently converting a RF into a digital signal, comprising:
a. receiving a RF signal,
b. down-converting said received RF signal to a base-band frequency range to obtain a base-band signal,
c. up-converting said base-band signal to a low intermediate frequency range to obtain a low IF signal, and
d. converting said low IF signal into a digital signal.

2. The method of claim 1, wherein said down-converting of said received RF signal to a base-band frequency range includes demodulating said RF signal with a quadrature demodulator, and wherein said up-converting of said base-band signal to a low intermediate frequency range includes modulating said base-band signal with a quadrature modulator.

3. The method of claim 2, wherein said demodulating of said RF signal with a quadrature demodulator includes demodulating said RF signal with a double-balanced quadrature demodulator.

4. The method of claim 2, wherein said quadrature demodulator is a sub-harmonic quadrature demodulator.

5. The method of claim 2, wherein said modulating, of said base-band signal with a quadrature modulator includes modulating said base-band signal with au image-reject quadrature modulator.

6. The method of claim 3, wherein said modulating of said base-band signal with a quadrature modulator includes modulating said base-band signal with an image-reject quadrature modulator.

7. The method of claim 4, wherein said modulating of said base-band signal with a quadrature modulator includes modulating said base-band signal with an image-reject quadrature modulator.

8. A method for efficiently converting a digital signal into a RF signal for RF transmission, comprising:
a. generating a digital signal in a low intermediate frequency range
b. converting said digital signal into an analog signal to obtain a low IF signal,
c. down-converting said low IF signal to a base-band frequency range to obtain a base-band signal, and
d. up-converting said base-band signal to a RF signal used for RF transmission.

9. The method of claim 8, wherein said down-converting of said low IF signal to a base-band frequency range includes using a quadrature demodulator, and wherein said up-converting of said base-band signal to a RF signal includes using a quadrature modulator.

10. The method of claim 9, wherein said using a quadrature modulator includes modulating said base-band with a double-balanced quadrature modulator.

11. The method of claim 9, wherein said quadrature modulator is a sub-harmonic quadrature modulator.

12. A receiving system for converting RF into digital signals, comprising:
a. a down-converter used to convert an analog RF signal into a base-band signal, and
b. an up-converter connected to said down-converter and used to convert said base-band signal into a low intermediate frequency signal which is further processed into a digital signal.

13. The system of claim 12, wherein said down-converter and said up converter include respectively a down-converter quadrature demodulator and an up-converter quadrature modulator.

14. The system of claim 12, implemented on a RFIC.

15. The system of claim 13, wherein said down-converter quadrature demodulator includes a double balanced quadrature demodulator.

16. The system of claim 13, wherein said up-converter quadrature modulator includes an image-reject quadrature modulator.

17. The system of claim 14, wherein said RFIC is manufactured using a technology selected from the group consisting of SiGe and RF CMOS technologies.

18. The system of claim 13, wherein said quadrature demodulator includes a sub-harmonic quadrature demodulator.

19. The system of claim 15, wherein said up-converter quadrature modulator includes an image-reject quadrature modulator.

20. The system of claim 18, wherein said up-converter quadrature modulator includes an image-reject quadrature modulator.

21. A system for converting a digital signal into a RF signal, comprising:
a. a down-converter used to convert a low intermediate frequency analog signal obtained from the digital signal into a base-band signal, and
b. an up-converter connected to said down-converter and used to convert said low intermediate frequency signal into a RF signal.

22. The system of claim 21, wherein said down-converter and said up-converter include, respectively, a down-converter quadrature demodulator and an up-converter quadrature modulator.

23. The system of claim 21, implemented on a RFIC.

24. The system of claim 23, wherein said RFIC is manufactured using a technology selected from the group consisting of SiGe and RF CMOS technologies.

25. An efficient, power saving receiver system for converting an input analog RF signal into a digital signal, comprising:
a. a RF plus IF section that generates a low intermediate frequency signal that is further processed into the digital signal,
b. a digital section connected to said RF plus IF section to process the digital signal, and
c. detector means coupled to sample said low intermediate frequency signal between, said RF plus IF section and said digital section, whereby said detector means enable stand-by (power-save) mode operation by turning on and off the digital part of the system.

26. The system of claim 25, wherein said RF plus IF section includes:
i. a down-converter used to convert the analog RF signal into a base-band signal, and
ii. an up-converter connected to said down-converter and used to convert said base-band signal into said low intermediate frequency signal.

27. A system for reception and transmission of RF signals belonging to either a RF low frequency band or a RF high frequency band, comprising:
i. a receiver for converting either the low frequency band or the high frequency band RF signals to base-band or intermediate frequency, wherein the conversion of the high band RF signals is obtained by standard down-conversion, and wherein the conversion of the low band RF signals is obtained by first up-converting them into outcome high band RF signals, and then down-converting said outcome high band RF signals, and
ii. a transmitter for converting base-band or intermediate frequency signals into either low band or high band RF signals for RF transmission, wherein said conversion to the high band RF signals is performed by standard up-conversion, and wherein said conversion to the low band RF signals is obtained by first up-converting said base-band or intermediate frequency signals to obtain outcome high band RF signals, and then down-converting said high band outcome RF signals.

28. The system of claim 27, wherein said conversion of said low band signals obtained by first up-converting them into high band signals is performed in a block up-converter, and wherein said down conversion to a low band is performed in a block down-converter.

29. The system of claim 28, wherein said high band signals and said low band signals are respectively 5 GHz and 2.4 GHz signals according to the IEEE 802.11a, IEEE802.11b and IEEE802.11g standards.
